(19) United States
(12) Patent Application Publication
(10) Pub. No.: US 2025/0167750 A1
(43) Pub. Date: May 22, 2025

(54) Multilayer Filter, Multilayer Filter Assembly, and Methods for Forming a Multilayer Filter

(71) Applicant: KYOCERA AVX Components Corporation, Fountain Inn, SC (US)

(72) Inventors: Cory Nelson, Simpsonville, SC (US); Marianne Berolini, Greer, SC (US); Jonathan Herr, Taylors, SC (US)

(21) Appl. No.: 18/944,067

(22) Filed: Nov. 12, 2024

Related U.S. Application Data
(60) Provisional application No. 63/601,798, filed on Nov. 22, 2023.

(51) Int. Cl. H03H 7/01; H03H 3/00

(52) U.S. Cl. CPC H03H 7/0153; H03H 3/00

(57) ABSTRACT

Filters, filter assemblies, and methods of forming filters are provided. For example, a filter includes a plurality of dielectric layers stacked in a Z-direction to form a substrate having a top and a bottom, and at least one conductive layer is formed over a dielectric layer. The conductive layer is positioned at a location along the Z-direction between the top and bottom of the substrate that is about 200 μm or less from the bottom of the substrate. An assembly includes the filter attached to a device substrate. A method of forming the filter includes forming the dielectric layers and the at least one conductive layer, such as by forming the conductive layer over a dielectric layer, and stacking the plurality of layers to form a substrate with the conductive layer disposed about 200 μm or less from a bottom of the substrate.

### RELATED APPLICATION

The present application is based upon and claims priority to U.S. provisional patent application Ser. No. 63/601,798, having a filing date of Nov. 22, 2023, which is incorporated herein by reference.

### BACKGROUND OF THE INVENTION

Electric filters perform many functions and are employed in a variety of electrical devices. Filtering of high frequency signals, such as high frequency radio signal communication, has recently increased in popularity. For example, the demand for increased data transmission speed for wireless connectivity has driven demand for high frequency components, including those configured to operate at high frequencies, including 5G spectrum frequencies. Current high frequency filters typically employ waveguide or cavity designs. The performance characteristics of such designs, however, are difficult to tailor or customize. Further, unwanted interference can adversely affect filter performance. As such, a high frequency multilayer filter, such as a high frequency multilayer filter having one or more features for reducing interference, would be welcomed in the art.

### SUMMARY OF THE INVENTION

In accordance with one embodiment of the present invention, a filter includes a plurality of dielectric layers. The plurality of dielectric layers are stacked in a Z-direction to form a substrate having a top and a bottom. The filter further includes at least one conductive layer formed over a dielectric layer of the plurality of dielectric layers. The at least one conductive layer is positioned at a location along the Z-direction between the top and the bottom of the substrate. The location along the Z-direction is about 200 μm or less from the bottom of the substrate.

In accordance with another embodiment of the present invention, an assembly includes a device and a filter. The device has a device substrate defining a mounting surface. The filter is attached to the device substrate. The filter includes a plurality of dielectric layers. The plurality of dielectric layers stacked in a Z-direction to form a substrate having a top and a bottom. The filter also includes at least one conductive layer formed over a dielectric layer of the plurality of dielectric layers. The at least one conductive layer is positioned at a location along the Z-direction between the top and the bottom of the substrate, and the location along the Z-direction is about 200 μm or less from the bottom of the substrate.

In accordance with still another embodiment of the present invention, a method for forming a filter includes forming a plurality of dielectric layers and forming at least one conductive layer over a dielectric layer of the plurality of dielectric layers. The method further includes stacking the plurality of dielectric layers in a Z-direction to form a substrate having a top and a bottom. The at least one conductive layer is positioned at a location along the Z-direction between the top and the bottom of the substrate, and the location along the Z-direction is about 200 μm or less from the bottom of the substrate.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 illustrates a schematic top perspective view of an assembly of the present invention;

FIG. 2 illustrates a schematic top view of a filter of the assembly of FIG. 1;

FIG. 3 illustrates a schematic cross-sectional view of an assembly of the present invention;

FIG. 4 illustrates a schematic top perspective view of another assembly of the present invention;

FIG. 5 illustrates a schematic top view of a filter of the assembly of FIG. 4;

FIG. 6 illustrates a schematic cross-sectional view of an assembly of the present invention;

FIG. 7 provides a flow chart of a method for forming a filter of the present invention;

FIG. 8 illustrates insertion loss and return loss generated using a computer model of a filter of the present invention; and

FIG. 9 illustrates insertion loss and return loss generated using a computer model of another filter of the present invention.

Repeat reference to characters in the present specification and figures is intended to represent same or analogous features or elements of the invention.

### DETAILED DESCRIPTION OF THE INVENTION

It is to be understood by one of ordinary skill in the art that the present discussion is a description of exemplary embodiments only and is not intended as limiting the broader aspects of the present invention.

Generally speaking, the present invention is directed to multilayer filters, such as multilayer filters that are relatively thin and/or that include a plurality of vias defined along the perimeter of the filter. For example, a multilayer filter as described herein can include a plurality of layers that form a substrate with resonators printed on a layer of the plurality of layers such that the resonators are disposed at a location within the substrate of about 200 μm or less from an outer surface of the substrate. As another example, a multilayer filter as described herein can include a plurality of layers that form a substrate having a perimeter, with a plurality of vias defined along the perimeter of the substrate. The present invention also includes assemblies including such filters, as well as methods of forming such filters.

In some embodiments, a filter includes a plurality of dielectric layers that are stacked in a Z-direction to form a substrate having a top and a bottom. The filter further includes at least one conductive layer, which may be formed over a dielectric layer of the plurality of dielectric layers. For example, in some embodiments, a plurality of filter elements, such as resonators, may be printed or otherwise disposed on a dielectric layer to form a conductive layer. The conductive layer may be sandwiched within the plurality of dielectric layers such that the conductive layer is located a distance in the Z-direction of about 200 μm or less from an outer surface of the substrate. The outer surface may be, e.g., the bottom of the substrate, and two or more conductive pads or lands may be defined on the outer surface and electrically connected to the conductive layer by one or more vias. In some embodiments, the distance in the Z-direction from the outer surface to the conductive layer or resonators may be about 150 μm or less, such as 120 μm or less, such as 100 μm or less, such as 80 μm or less, such as 50 μm or less, or such as 20 μm or less. A first plurality of the dielectric layers define the substrate from the outer surface to the conductive layer, and a second plurality of the dielectric layers may be disposed over the conductive layer to sandwich the conductive layer within the stack of dielectric layers.

Such a distance from the outer surface (e.g., the bottom) of the filter substrate to the conductive layer may be result in a smaller or thinner filter than that of known filters, or at the least, the conductive layer may be located closer to the structure on which the filter is mounted than in typical known filter assemblies. More particularly, a multilayer filter as described herein may allow the resulting filter substrate (formed from a plurality of layers) to be relatively thin, e.g., compared to known filter substrates. Further, as the filter substrate thickness decreases, the element line width of the filter elements decreases. That is, the element line width (such as the resonator line width) decreases with filter substrate thickness. As such, a smaller filter footprint may be achieved, e.g., because less area is required for the filter elements. As the filter footprint decreases, return loss and insertion loss improves. As an alternative to thinner element widths, the reduced thickness filter as described herein may be used at higher frequencies with improved return loss and insertion loss. That is, rather than decreasing the element line widths as the filter substrate decreases, the element line widths may stay the same but the filter may be used for filtering higher frequencies.

It will be appreciated that the plurality of dielectric layers can provide stiffness or strength to the resulting substrate, which can allow the substrate to be thinner while retaining sufficient stiffness and/or strength to maintain the structural integrity of the filter. That is, the stack of layers provides the needed stiffness or strength while allowing the filter as described herein to be thinner than typical or known filters.

In some embodiments, a filter includes a plurality of dielectric layers including an outer dielectric layer. The plurality of dielectric layers are stacked in a Z-direction to form a substrate having a top and a bottom. The substrate defines a perimeter, and the outer dielectric layer is disposed at the top of the substrate. The filter further includes at least two conductive layers, at least one conductive layer of the plurality of conductive layers formed over a respective one dielectric layer of the plurality of dielectric layers and an outer conductive layer formed over the outer dielectric layer. The outer conductive layer can extend to the perimeter, i.e., to the edges of the outer dielectric layer. Moreover, a plurality of vias may be defined along the perimeter of the substrate, the plurality of vias extending from the outer conductive layer to the bottom of the substrate.

The vias may be grounded such that the outer conductive layer forms a grounded cover or shield of the filter. That is, one or more of the vias defined along the perimeter of the substrate can be electrically connected to a ground and electrically connected to the outer conductive layer, which can include a conductive material formed over a dielectric layer such that the grounded via(s) connected thereto ground the outer conductive layer to form a shield. Such shield may provide protection from interference for the filter and/or may improve performance and/or rejection compared to filters having a similar footprint but lacking such grounded cover.

The plurality of dielectric layers in a filter as described herein may include one or more dielectric materials, e.g., as a filter substrate, as one or more dielectric layers, etc. In some embodiments, the one or more dielectric materials may have a low dielectric constant (K). The dielectric constant may be less than about 20, in some embodiments less than about 10, in some embodiments less than about 7.5, in some embodiments less than about 5, in some embodiments less than about 4.5, in some embodiments less than about 4, and in some embodiments less than about 3.5. For instance, in some embodiments, the dielectric constant may range from about 1.5 to about 20, in some embodiments from about 1.5 to about 10, in some embodiments from about 1.5 to about 7.5, and in some embodiments from about 2 to about 5.

Such a relatively low dielectric constant material may allow the dielectric layers to be very thin or ultrathin, which can allow the filter substrate to be thinner than typical filters. Although a relatively low dielectric constant material usually becomes brittle as its thickness is reduced or it is made thinner, the multilayer stack of dielectric layers and conductive layer(s) as described herein provides sufficient stiffness to avoid negative effects of brittleness of the individual layers. Further, lower dielectric constant materials may have better high frequency performance than higher dielectric contact materials. Accordingly, the present inventors have discovered that the combination of the plurality of dielectric layers formed from a relatively low dielectric constant material and the arrangement of the plurality of dielectric layers in a stack as described herein can result in smaller filters with improved high frequency performance than known filters. Moreover, the present inventors have discovered that incorporating a shield in the multilayer stack as described herein can provide the advantages of shielding without enlarging the filter footprint, i.e., the advantages of shielding may be achieved while maintaining the size improvements as described herein.

In some embodiments, the one or more dielectric materials may include organic dielectric materials. Example organic dielectric include polyphenyl ether (PPE) based materials, such as LD621 from Polyclad and N6000 series from Park/Nelco Corporation, liquid crystalline polymer (LCP), such as LCP from Rogers Corporation or W. L. Gore & Associates, Inc., hydrocarbon composites, such as 4000 series from Rogers Corporation, and epoxy-based laminates, such as N4000 series from Park/Nelco Corp. For instance, examples include epoxy based N4000-13, bromine-free material laminated to LCP, organic layers with high K material, unfilled high-K organic layers, Rogers 4350, Rogers 4003 material, and other thermoplastic materials such as polyphenylene sulfide resins, polyethylene terephthalate resins, polybutylene terephthalate resins, polyethylene sulfide resins, polyether ketone resins, polytetraflouroethylene resins and graft resins, or similar low dielectric constant, low-loss organic material.

In some embodiments, the dielectric material may be a ceramic-filled epoxy. For example, the dielectric material may include an organic compound, such as a polymer (e.g., an epoxy) and may contain particles of a ceramic dielectric material, such as barium titanate, calcium titanate, zinc oxide, alumina with low-fire glass, or other suitable ceramic or glass-bonded materials. In some embodiments, the dielectric material may be an organic compound such as an epoxy (with or without ceramic mixed in, with or without fiberglass), popular as circuit board materials, or other plastics common as dielectrics. In these cases, the conductor is usually a copper foil which is chemically etched to provide the patterns. In still further embodiments, dielectric material may comprise a material having a relatively high dielectric constant (K), such as one of NPO (COG), X7R, X5R X7S, Z5U, Y5V and strontium titanate. In such examples, the dielectric material may have a dielectric constant that is greater than 100, for example within a range from between about 100 to about 4000, in some embodiments from about 1000 to about 3000.

Other materials may be utilized, however, including, N6000, epoxy based N4000-13, bromine-free material laminated to LCP, organic layers with high K material, unfilled high-K organic layers, Rogers 4350, Rogers 4003 material (from the Rogers Corporation), and other thermoplastic materials such as hydrocarbon, Teflon, FR4, epoxy, polyamide, polyimide, and acrylate, polyphenylene sulfide resins, polyethylene terephthalate resins, polybutylene terephthalate resins, polyethylene sulfide resins, polyether ketone resins, polytetraflouroethylene resins, BT resin composites (e.g., Speedboard C), thermosets (e.g., Hitachi MCL-LX-67F), and graft resins, or similar low dielectric constant, low-loss organic material.

Additionally, in some embodiments, non-organic dielectric materials may be used including a ceramic, semi-conductive, or insulating materials, such as, but not limited to, sapphire, ruby, alumina (Al₂O₃), aluminum nitride (AlN), beryllium oxide (BeO), aluminum oxide (Al₂O₃), boron nitride (BN), silicon (Si), silicon carbide (SiC), silica (SiO₂), silicon nitride (Si₃N₄), gallium arsenide (GaAs), gallium nitride (GaN), zirconium dioxide (ZrO2), mixtures thereof, oxides and/or nitrides of such materials, or any other suitable ceramic material. Additional example ceramic materials include barium titanate (BaTiO₃), calcium titanate (CaTiO₃), zinc oxide (ZnO), ceramics containing low-fire glass, or other glass-bonded materials. Dielectric materials such as diamond may be used as well.

Suitable dielectric materials are generally electrically insulating and thermally conductive. For example, in some embodiments, the filter may include a filter substrate having a relatively high thermal conductivity, which may improve the device's power handling capabilities. For instance, the substrate can have a thermal conductivity that is greater than about 20 W/m·° C., in some embodiments greater than about 40 W/m·° C., in some embodiments greater than about 80 W/m·° C., and in some embodiments greater than about 100 W/m·° C.

The filter may be configured as one of a variety of suitable filter types, including, for example, a low pass filter, a high pass filter, or a bandpass filter. The filter may have a characteristic frequency (e.g., a low pass frequency, high pass frequency, an upper bound of a band pass frequency, or a lower bound of a band pass frequency (e.g., a stop band frequency)) that ranges from about 100 MHz to about 5 GHZ, or higher, such as about 10 GHZ, about 20 GHZ, about 30 GHz, about 50 GHZ, or higher. In some embodiments, the filter may have a characteristic frequency that ranges from about 150 MHz to about 4 GHZ, and in some embodiments from about 200 MHz to about 3 GHz. The characteristic frequency of the filter may have other ranges as well.

In some embodiments, the filter may include a signal path having an input and an output. For instance, a conductive material may be formed over a dielectric layer of the plurality of dielectric layers of the filter substrate to form a conductive layer and define the signal path. The signal path can include a plurality of elements, such as resonators or the like, formed from the conductive material. One or more of the elements may have an element line width in an X-Y plane extending perpendicular to the Z-direction. The element line width may be directly related to the thickness of the substrate such that the element line width decreases as the thickness of the substrate decreases. For example, a thinner substrate may allow one or more elements of the signal path to have thinner or reduced line widths. The element line width may be about 500 μm or less, such as about 400 μm or less, about 250 μm or less, about 100 μm or less, about 75 μm or less, about 50 μm or less, or about 20 μm or less. In some embodiments, the element line width may be within a range of about 10 μm to about 500 μm, such as about 20 μm to about 400 μm or about 50 μm to about 200 μm.

As used herein, a conductive layer “formed over” a dielectric layer may refer to a conductive layer formed directly on the dielectric layer. However, one or more thin intermediate layers or coatings may be located between the conductive layer and/or dielectric layer.

The conductive material may be one or more of a variety of conductive materials. For example, the conductive material used to define, e.g., the plurality of elements may include copper, nickel, gold, silver, or other metals or alloys.

The conductive layer(s) may be formed using a variety of suitable techniques. Subtractive, semi-additive or fully additive processes may be employed with panel or pattern electroplating of the conductive material followed by print and etch steps to define the patterned conductive layers. Photolithography, plating (e.g., electrolytic), sputtering, vacuum deposition, printing, or other techniques may be used to form the conductive layers. For example, a thin layer (e.g., a foil) of a conductive material may be adhered (e.g., laminated) to a surface of a dielectric layer. The thin layer of conductive material may be selectively etched using a mask and photolithography to produce a desired pattern of the conductive material on the surface of the dielectric material.

As previously described, in some embodiments the filter may include a plurality of vias. The plurality of vias may be defined along the perimeter of the filter substrate. For example, the plurality of vias may surround a signal path of the filter. In some embodiments, the plurality of vias may be defined at regular intervals and may be described as a ring of vias.

As previously stated, the plurality of conductive layers may include an outer conductive layer formed over an outer dielectric layer of the plurality of dielectric layers. In some embodiments, the outer conductive layer is formed over the outer dielectric layer such that the outer conductive layer is formed over the perimeter of the substrate and contacts the plurality of vias. The plurality of vias may be electrically connected to ground such that the outer conductive layer forms a shield for the filter.

In some embodiments, the perimeter of the filter substrate has a generally rectangular shape including four sides. A portion of the plurality of vias may be defined along each of the four sides of the perimeter.

In some embodiments, at least one via of the plurality of vias is plated with a conductive material, which may include, e.g., copper, nickel, gold, silver, or other metals or alloys. In some embodiments, at least one via of the plurality of vias is filled with a conductive material. The vias may be formed by drilling (e.g., mechanical drilling, laser drilling, etc.) through holes and plating or filling the through holes with a conductive material, for example, using electroless plating or seeded copper. As described, one or more vias may be filled with conductive material such that a solid column of conductive material is formed. Alternatively, or additionally, the interior surface of one or more of the through holes may be plated such that one or more vias are hollow but are lined with conductive material.

In some embodiments, the filter includes a cover. The cover is one or more layers of material that are in addition to the plurality of dielectric layers and the plurality of conductive layers that form the filter substrate. For example, the cover may be formed over the top of the filter substrate and/or over one or more sides of the filter substrate that extend between the top and the bottom of the filter substrate.

The cover can provide stiffness to the filter, which can improve the filter's utility or usability. Further, the cover may be electrically isolative and thermally conductive, e.g., to conduct heat away from the filter for heat or thermal management. The cover may be formed from, e.g., aluminum nitride (AlN), alumina (Al₂O₃), beryllium oxide (BeO), diamond, or other suitable electrically insulative, thermally conductive material such as the ceramics and the like described elsewhere herein.

As previously described, the filter includes at least one conductive layer. In some embodiments, at least two conductive layers of the plurality of conductive layers are formed over two different dielectric layers of the plurality of dielectric layers such that the at least two conductive layers are positioned at different locations along the Z-direction.

The plurality of dielectric layers, including the one or more conductive layers formed over one or more of the dielectric layers of the plurality of dielectric layers, may be stacked along the Z-direction. In some embodiments, when stacked, the conductive layer having the one or more elements defined thereon may be positioned at a location along the Z-direction such that the conductive layer is sandwiched in the remaining dielectric layers. For example, a first plurality of dielectric layers having a first thickness may be positioned below the conductive layer along the Z-direction, and a second plurality of dielectric layers having a second thickness may be positioned above the conductive layer along the Z-direction. In such embodiments, the first plurality of dielectric layers may define the bottom of the filter substrate, and the second plurality of dielectric layers may define the top of the filter substrate. As such, the conductive layer may be positioned at a location along the Z-direction from the bottom of the filter substrate that is equal to the first thickness and may be positioned at a location along the Z-direction from the top of the filter substrate that is equal to the second thickness.

In embodiments including an outer conductive layer that defines a shield for the filter, the outer conductive layer may be positioned on top of the second plurality of dielectric layers such that the conductive layer having the one or more elements defined thereon is sandwiched in the dielectric layers and the outer conductive layer is positioned on top of the dielectric layers. In some embodiments, an outer layer, such as a solder mask, a layer of dielectric material, or the like, may be disposed over the outer conductive layer such that the outer layer defines the top of the filter substrate. In other embodiments not including the outer layer, the outer conductive layer may define the top of the filter substrate, and the first plurality of dielectric layers may define the bottom of the filter substrate. In either embodiment, the conductive layer defining the one or more filter elements may be positioned at a location along the Z-direction from the bottom of the filter substrate that is equal to the first thickness and may be positioned at a location along the Z-direction from the outer conductive layer that is equal to the second thickness.

A filter as described herein may be incorporated into an assembly. In some embodiments, an assembly may include a device and a filter as described herein. The device may include a device substrate and a ground defined on the device substrate. The filter may be attached to the device substrate. The device substrate may be, e.g., a printed circuit board (PCB) or the like formed from any suitable material.

In some embodiments, the device of the assembly may include a mounting surface, which may extend in a mounting plane parallel to an X-Y plane. The plurality of dielectric layers (and the at least one conductive layer formed over a dielectric layer of the plurality of dielectric layers) of the filter may each extend in parallel to a plane that extends in a longitudinal direction and a lateral direction, and in some embodiments, the plane may be parallel to the X-Y plane such that the filter is attached to the device with the plurality of dielectric layers extending parallel to the mounting surface. In other embodiments, the filter may be attached to the device such that the plurality of dielectric layers extend perpendicular to the mounting surface.

In embodiments of the assembly in which the filter defines a plurality of vias extending from an outer conductive layer, one or more of the vias may be electrically connected to the ground defined on the device substrate. As such, the vias and outer conductive layer may form a grounded cover or shield for the filter, which can provide protection from interference.

The present subject matter also includes methods for forming filters and methods for forming assemblies as described herein. As one example, a method for forming a filter may include forming a plurality of dielectric layers; forming at least one conductive layer over a dielectric layer; and stacking the plurality of dielectric layers in a Z-direction to form a substrate having a top and a bottom. When the plurality of dielectric layers are stacked in the Z-direction, the at least one conductive layer may be positioned at location of about 200 μm or less from an outer surface of the substrate. For example, the conductive layer may be positioned at a location within the stack of dielectric layers such that the conductive layer is about 200 μm or less from the bottom of the substrate. In some embodiments, the method may include defining a plurality of vias along a perimeter of the substrate, e.g., such that the plurality of vias extend from an outer conductive layer formed over a dielectric layer of the plurality of dielectric layers to the bottom of the substrate.

In some embodiments, the filter may generally be compact. For example, the filter may have a length that is less than about 150 mm, in some embodiments less than about 100 mm, in some embodiments less than about 80 mm, in some embodiments less than about 50 mm, in some embodiments less than about 30 mm, in some embodiments less than about 15 mm, in some embodiments less than about 8 mm, in some embodiments less than about 5 mm, and in some embodiments less than about 1 mm. Further, the filter may have a width that is less than about 100 mm, in some embodiments less than about 60 mm, in some embodiments less than about 40 mm, in some embodiments less than about 20 mm, in some embodiments less than about 15 mm, in some embodiments less than about 10 mm, in some embodiments less than about 5 mm, in some embodiments less than about 3 mm, and in some embodiments less than about 1 mm.

The length of the filter may be measured in a longitudinal or X-direction, and the width of the filter may be measure in a lateral or Y-direction. In some embodiments, the length may include the cover layer that extends longitudinally beyond one or both longitudinal ends of the filter substrate. Further, the width of the filter may include the cover layer that extends laterally beyond one or both lateral sides of the filter substrate. In other embodiments, the length and/or the width of the filter may be the same as the length and/or width of the filter substrate. In any event, in at least some embodiments, each of the length and the width of the filter may be greater than the thickness of the substrate of the filter from an outer surface of the filter substrate to a signal path defined on a dielectric layer sandwiched in the filter substrate. For example, a ratio of the length of the filter to the distance from the bottom of the filter substrate to the conductive layer including the signal path may be about 10 or greater, such as about 20 or greater, about 25 or greater, about 30 or greater, or about 50 or greater. In some embodiments, a ratio of the width of the filter to the distance from the bottom of the filter substrate to the conductive layer including the signal path may be about 5 or greater, such as about 10 or greater, about 20 or greater, about 25 or greater, about 30 or greater, or about 50 or greater.

As used herein, “formed over,” may refer to a layer that is directly in contact with another layer. However, intermediate layers may also be formed therebetween. Additionally, when used in reference to a bottom surface, “formed over” may be used relative to an exterior surface of the component. Thus, a layer that is “formed over” a bottom surface may be closer to the exterior of the component than the layer over which it is formed.

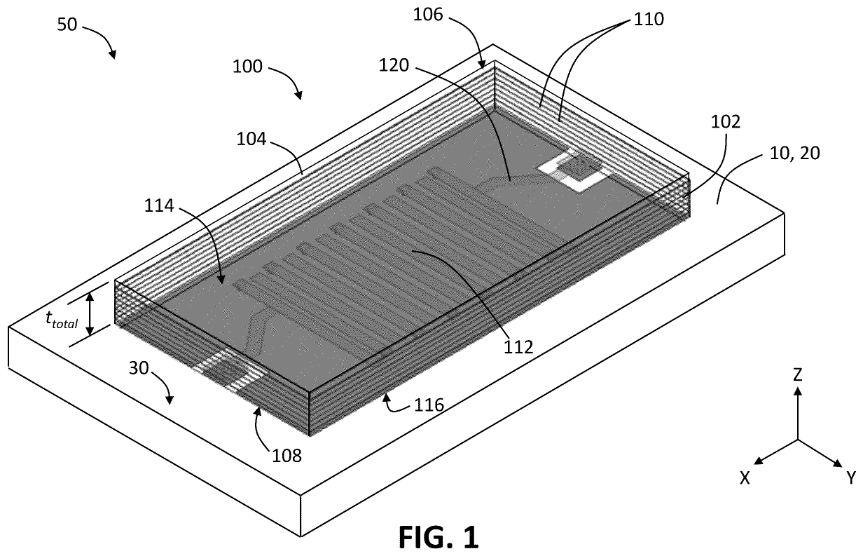

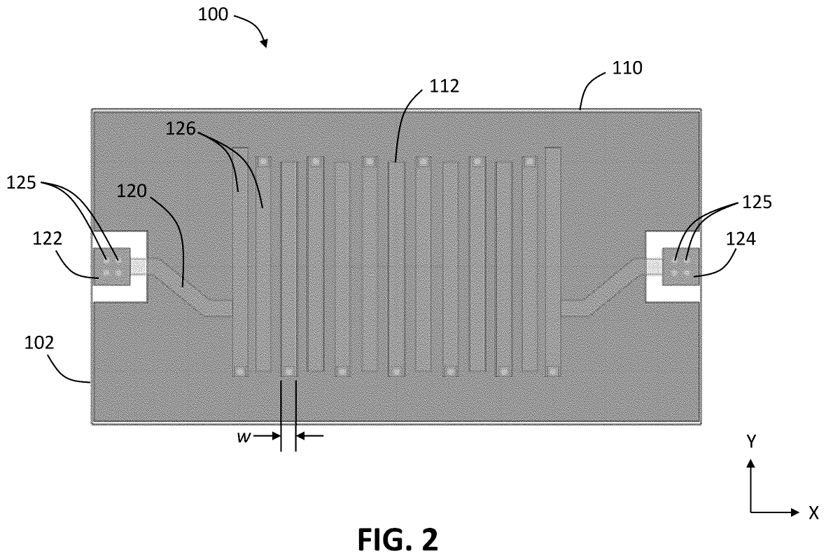

Referring now to the figures, various embodiments of the present invention will now be described in more detail. FIG. 1 provides a schematic top perspective view of an assembly 50, including a filter 100 disposed on device substrate 20 of a device 10. More particularly, the filter 100 is disposed on a mounting surface 30 of the device substrate 20. FIG. 2 provides a schematic top view of the filter 100. It will be appreciated that the various components shown in FIGS. 1 and 2 are shown as transparent to depict, e.g., any conductive patterns disposed on layers sandwiched within the stack of layers forming the filter 100.

As shown in FIG. 1, the filter 100 includes a filter substrate 102 and a cover 104. The filter 100 defines an upper surface 106 and a lower surface 108 opposite the upper surface 106 along a vertical direction Z, which also may be referred to as the Z-direction. The upper surface 106 extends in a first plane parallel to an X-Y plane defined by a longitudinal direction X and a lateral direction Y. The lower surface 108 of the filter 100 extends in a second plane parallel to the X-Y plane. As such, the first plane and the second plane are parallel to one another as well as the X-Y plane.

Keeping with FIG. 1, the filter substrate 102 includes a plurality of dielectric layers 110 and a conductive layer 112 formed over a dielectric layer 110 of the plurality of dielectric layers 110. As described elsewhere herein, the plurality of dielectric layers 110 may be formed from one or more of a variety of dielectric materials, such as organic, ceramic, and/or other dielectric materials. Similarly, the conductive layer 112 may include one or more filter elements formed from one or more of a variety of conductive materials, such as metals, metal alloys, and/or other conductive materials. The conductive layer 112 may be formed using any suitable process, such as one or more of the exemplary processes described above for depositing conductive material on a dielectric material.

In the embodiment of FIGS. 1 and 2, the plurality of dielectric layers 110 are stacked in the Z-direction to form the filter substrate 102. The first conductive layer 112a and the second conductive layer 112b may be stacked in the filter substrate 102 such that the conductive layers 112a, 112b are spaced apart from one another along the Z-direction.

As further shown in FIG. 1, the substrate 102 has a top 114 and a bottom 116. The substrate 102 may have a thickness t in the Z-direction between the top 114 and the bottom 116 that is about 50 μm or less. For instance, the thickness t may be about 50 μm or less, about 40 μm or less, about 30 μm or less, or about 20 μm or less.

Moreover, in the embodiment of FIG. 1, the filter 100 includes a cover 104, which may be, e.g., one or more layers of material that are in addition to the plurality of dielectric layers 110 and the plurality of conductive layers 112 that form the filter substrate 102. A total thickness tₜₒₜₐₗ of the filter 100 includes the thickness t of the substrate 102 and the thickness of the cover 104. For example, the total thickness tₜₒₜₐₗ of the filter 100 is defined in the Z-direction between the upper surface 106 and the lower surface 108 of the filter 100. The total thickness tₜₒₜₐₗ may be about 2000 μm or less, such as about 1500 μm or less, such as about 1250 μm or less, such as about 1000 μm or less, such as about 800 μm or less. The cover 104 may be formed from one or more of a variety of materials as described in greater detail elsewhere herein.

The filter 100 may also include a signal path 120 having an input 122 and an output 124. Referring to FIG. 2, the signal path 120 can include an element 126 formed from one or more conductive layers 112. In the depicted embodiment, the signal path 120 includes a plurality of elements 126, such as resonators or the like, formed from one conductive layer 112. For example, each element 126 is formed from conductive material deposited on one dielectric layer 110 of the plurality of dielectric layers 110.

The input 122 and the output 124 may be formed on the bottom 116 of the substrate 102. For instance, each of the input 122 and the output 124 can be a land or pad formed on the bottom 116 of the substrate 102, e.g., the input 122 can be an input contact pad and the output 124 can be an output contact pad. As shown in FIG. 2, the signal path 120, which includes the plurality of elements 126, may be electrically connected to each of the input 122 and the output 124 through one or more vias 125. A respective one via 125 may extend through the substrate 102 from the signal path 120, formed on a conductive layer 112 disposed in the stack of dielectric layers 110, to one of the input 122 or the output 124.

In the embodiment of FIG. 2, each element 126 has an element line width w in the X-Y plane, which extends perpendicular to the vertical or Z-direction. The element line width w generally may be about 500 μm or less, such as within a range of about 10 μm to about 500 μm, about 20 μm to about 400 μm, or about 50 μm to about 200 μm.

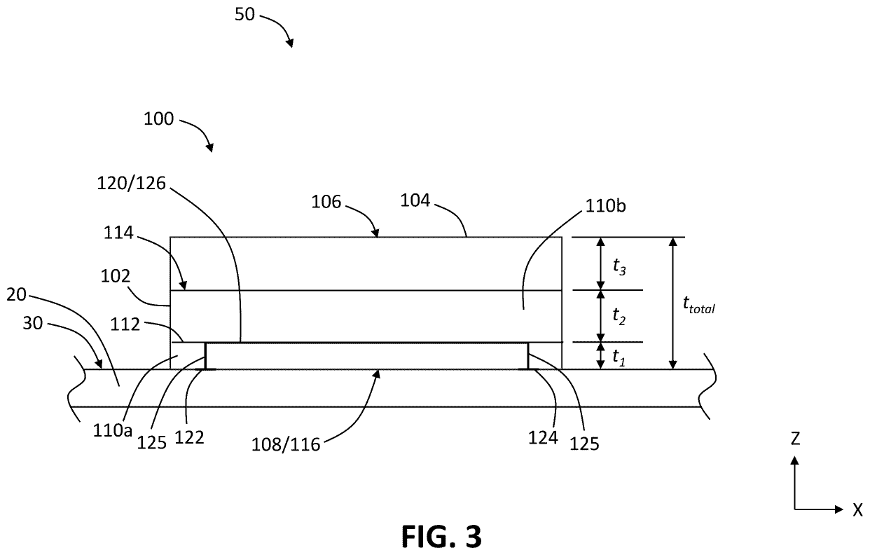

Turning to FIG. 3, a schematic cross-section view is provided of the assembly 50 including the filter 100. As shown in FIG. 3, the signal path 120, formed from one or more elements 126 as described above, is disposed on a conductive layer 112. The conductive layer 112 is sandwiched in a plurality of dielectric layers 110 (which, for the sake of clarity, are not shown individually in FIG. 3), e.g., the conductive layer 112 is positioned between a first plurality 110a of dielectric layers 110 and a second plurality 110b of dielectric layers 110 such that the conductive layer 112 is positioned at a location along the Z-direction between the top 114 and the bottom 116 of the substrate 102. The bottom 116 of the substrate 102 is positioned adjacent the mounting surface 30 of the device 10. In the depicted embodiment, the first plurality 110a of dielectric layers 110 has a thickness t₁ in the Z-direction, and the second plurality 110b of dielectric layers 110 has a thickness t₂ in the Z-direction. Accordingly, the conductive layer 112 is positioned at the location t₁ along the Z-direction from the bottom 116 of the substrate 102.

The thickness t₁ of the first plurality 110a of dielectric layers 110 may be about 200 μm or less. For example, the thickness t₁ of the first plurality 110a of dielectric layers 110 may be within a range of about 20 μm to about 200 μm, such as within a range of about 25 μm to about 150 μm, a range of about 50 μm to about 120 μm, or a range of about 60 μm to about 90 μm. As such, in embodiments in which the conductive layer 112 includes a plurality of elements 126 formed as resonators, the resonators are disposed at a location within the substrate 102 of about 200 μm or less from an outer surface (such as the bottom surface 116) of the substrate 102.

The thickness t₂ of the second plurality 110b of dielectric layers 110 may be about 1000 μm or less. For instance, the thickness t₂ of the second plurality 110b of dielectric layers 110 may be within a range of about 100 μm to about 1000 μm, such as within a range of about 200 μm to about 800 μm, a range of about 300 μm to about 700 μm, or a range of about 400 μm to about 600 μm.

As further illustrated in FIG. 3, the cover 104 may have a cover thickness t₃ in the Z-direction. The cover thickness t₃ may be about 1000 μm or less. For example, the cover thickness t₃ may be within a range of about 100 μm to about 1000 μm, such as within a range of about 200 μm to about 800 μm, a range of about 300 μm to about 700 μm, or a range of about 400 μm to about 600 μm.

It will be appreciated that the thickness of the substrate 102 is the sum of the thickness t₁ of the first plurality 110a of dielectric layers 110 and the thickness t₂ of the second plurality 110b of dielectric layers 110. As such, the thickness of the substrate 102 may be about 1000 μm or less, such as about 800 μm or less, about 500 μm or less, or about 400 μm or less. Moreover, the total thickness tₜₒₜₐₗ of the filter 100 is the sum of the thickness of the substrate 102 and the cover 104, or the sum of the thickness t₁ of the first plurality 110a of dielectric layers 110, the thickness t₂ of the second plurality 110b of dielectric layers 110, and the cover thickness t₃ of the cover 104. As such, the thickness of the substrate 102 may be about 2200 μm or less, such as about 2000 μm or less, about 1500 μm or less, about 1000 μm or less, about 800 μm or less, about 500 μm or less, or about 400 μm or less. For instance, the total thickness tₜₒₜₐₗ of the filter 100 may be within a range of about 220 μm to about 2200 μm, a range of about 300 μm to about 1500 μm, a range of about 400 μm to about 1000 μm, or a range of about 400 μm to about 800 μm.

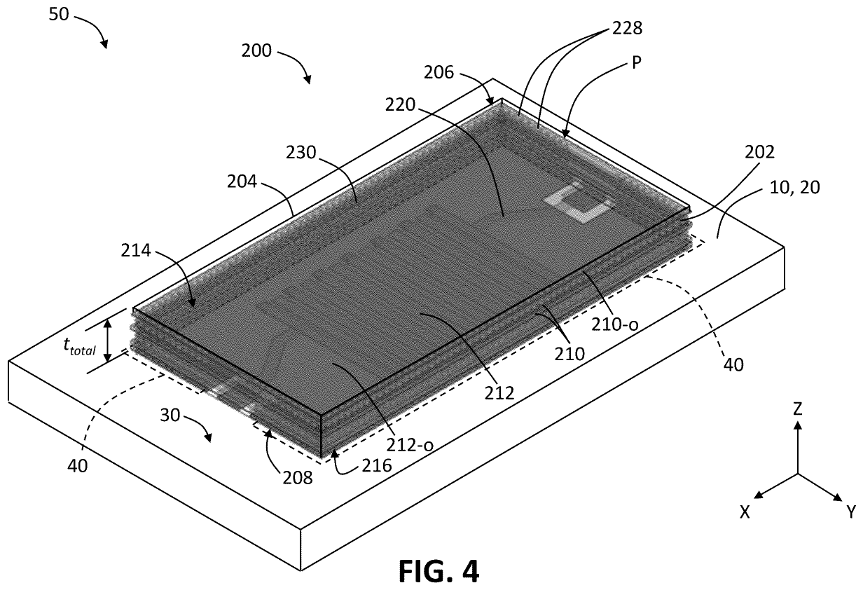

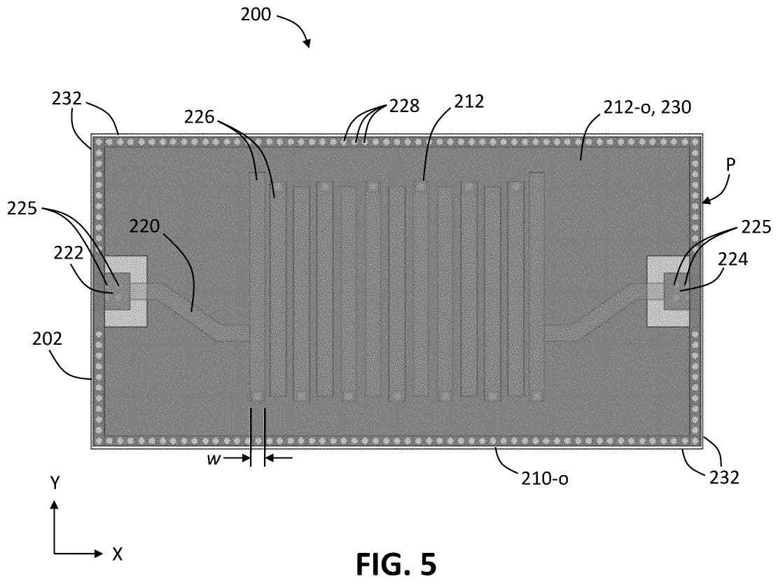

Referring now to FIGS. 4 and 5, FIG. 4 provides a schematic top perspective view of another embodiment of an assembly 50 including a device 10 and a filter 200, and FIG. 5 provides a schematic top view of the filter 200. As depicted in FIGS. 4 and 5, the filter 200 is generally similar to the filter 100 depicted in FIGS. 1 and 2 and the assembly 50 is generally similar to the assembly 50 shown in FIG. 1, and similar reference numbers are used in FIGS. 4 and 5 to indicate the same or similar features to those illustrated in FIGS. 1 and 2. For example, the filter 200 includes a plurality of dielectric layers 210 and a plurality of conductive layers 212, including an outer dielectric layer. The plurality of dielectric layers 210 are stacked in the vertical or Z-direction to form a substrate 202 having a top 214 and a bottom 216. At least one conductive layer 212 of the plurality of conductive layers 212 is formed over a respective one dielectric layer 210 of the plurality of dielectric layers 210 of the filter 200. In some embodiments, the substrate 202 has a thickness t in the Z-direction that is about 50 μm or less.

Moreover, the depicted filter 200 includes a cover 204, which may be, e.g., one or more layers of material that are in addition to the plurality of dielectric layers 210 and the plurality of conductive layers 212 that form the filter substrate 202. A total thickness tₜₒₜₐₗ of the filter 200 includes the thickness t of the substrate 202 and the thickness of the cover 204. For example, the total thickness tₜₒₜₐₗ of the filter 200 shown in FIG. 4 is defined in the Z-direction between an upper surface 206 and a lower surface 208 of the filter 200. The total thickness tₜₒₜₐₗ may be about 200 μm or less, such as described with respect to the filter 100 of FIG. 1, and the cover 204 may be formed from one or more of a variety of materials as described in greater detail elsewhere herein. Further, as in FIGS. 1 and 2, the cover 204, dielectric layers 210, and conductive layers 212 are shown as transparent to depict, e.g., any conductive patterns disposed on layers sandwiched in the stack of dielectric and conductive layers 210, 212.

Referring to FIGS. 4 and 5, the filter 200 may also include a signal path 220 having an input 222 and an output 224. The signal path 220 can include an element 226 formed from one or more conductive layers 212. In the depicted embodiment, the signal path 220 includes a plurality of elements 226, such as resonators or the like, formed from one conductive layer 212. For example, each element 226 is formed from conductive material deposited on one dielectric layer 210 of the plurality of dielectric layers 210.

In the embodiment of FIGS. 4 and 5, the input 222 and the output 224 are formed on the bottom 216 of the substrate 202. For instance, each of the input 222 and the output 224 is configured as a land or pad formed on the bottom 216 of the substrate 202, e.g., the input 222 can be an input contact pad and the output 224 can be an output contact pad. The signal path 220, which includes the plurality of elements 226, is electrically connected to each of the input 222 and the output 224 through a plurality of vias 225. A respective one via 225 may extend through the substrate 202 from the signal path 220, formed on a conductive layer 212 disposed in the stack of dielectric layers 210, to one of the input 222 or the output 224.

As shown in FIG. 5, each element 226 has an element line width win the X-Y plane, which extends perpendicular to the vertical or Z-direction. The element line width w generally may be about 500 μm or less, such as within a range of about 10 μm to about 500 μm, about 20 μm to about 400 μm, or about 50 μm to about 200 μm. The signal path may include one or more filter elements 226 such as resonators or the like, e.g., as described elsewhere herein.

As shown in FIG. 4, the filter 200 may be incorporated into an assembly 50 including a device 10 having a device substrate 20 and a ground 40 defined on the device substrate 20. The filter 200 may be attached to the device substrate 20, e.g., on a mounting surface 30 of the device substrate 20. The device substrate 20 may be, e.g., a printed circuit board (PCB) or the like formed from any suitable material.

Keeping with FIG. 4, the mounting surface 30 extends in a mounting plane parallel to an X-Y plane defined by a longitudinal or X-direction and a lateral or Y-direction. In the depicted embodiment, the plurality of dielectric layers 210 and the plurality of conductive layers 212 of the filter 200 each extend in the X-direction and the Y-direction parallel to the X-Y plane such that the filter 200 is attached to the device 10 with the plurality of dielectric layers 210 and the plurality of conductive layers 212 extending parallel to the mounting surface 30 of the device 10.

In the embodiments of FIGS. 4 and 5, the plurality of dielectric layers 210 of the filter 200 includes an outer dielectric layer 210-o, with an outer conductive layer 212-o formed over the outer dielectric layer 210-o. The outer dielectric layer 210-o and outer conductive layer 212-o is disposed at the top of the substrate 202, e.g., the outer dielectric layer 210-o having the outer conductive layer 212-o formed thereover defines the top 214 of the filter substrate 202.

Further, the substrate 202 defines a perimeter P. As shown in FIGS. 4 and 5, a plurality of vias 228 may be defined along the perimeter P of the substrate 202. For example, the plurality of vias 228 may surround a signal path 320 of the filter 200. In some embodiments, the plurality of vias 228 may be defined at regular intervals and may be described as a ring of vias 228, which ring the filter 200.

In the depicted embodiment, the outer conductive layer 212-o extends to the perimeter P of the substrate 202, and the plurality of vias 228 extend from the outer conductive layer 212-o to the bottom 216 of the substrate 202. The vias 228 may be through holes filled with conductive material such that a solid column of conductive material is formed, or the vias 228 may be through holes having the interior surfaces thereof plated with conductive material such that the vias 228 are hollow. In various embodiments, each of the vias 228 may be filled, each of the vias 228 may be plated, hollow vias, or a mix of filled and plated, hollow vias 228 may be used. Exemplary conductive materials and methods for forming the via through holes are described elsewhere herein.

The vias 228 may be grounded such that the outer conductive layer 212-o forms a grounded cover of the filter 200. For example, one or more of the vias 228 defined along the perimeter P of the substrate 202 can be electrically connected to a ground, e.g., a ground 40 defined on the device substrate 20, and electrically connected to the outer conductive layer 212-o. The outer conductive layer 212-o can include a conductive material formed over the outer dielectric layer 210-o such that the grounded via(s) 228 connected thereto ground the outer conductive layer 212-o to form a grounded cover or shield 230 for the filter 200. Such grounded cover or shield 230 may provide protection from interference for the filter 200 and/or may improve performance and/or rejection compared to filters having a similar footprint but lacking a shield.

As previously stated, the plurality of conductive layers 212 may include an outer conductive layer 212-o formed over an outer dielectric layer 210-o of the plurality of dielectric layers 210. In some embodiments, the outer conductive layer 212-o is formed over the outer dielectric layer 210-o such that the outer conductive layer 212-o is formed over the perimeter P of the substrate 202, e.g., in contact with the plurality of vias 228.

The substrate 202 may have any suitable shape, such as a rectangular parallelopiped shape. In such embodiments, the perimeter P of the filter substrate 202 has a generally rectangular shape including four sides 232. As shown in FIGS. 4 and 5, portion of the plurality of vias 228 may be defined along each of the four sides 232 of the perimeter P.

The ground 40 of the device 10 may have any suitable shape. For example, the ground 40 may be shaped in strips corresponding to the layout of the vias 228 along the sides 232 of the perimeter P of the filter substrate 302. In other embodiments, the strips may be connected and/or the ground 40 may have a generally rectangular shape. For instance, the ground 40 may have a generally rectangular shape that is at least coextensive with the bottom 216 of the filter substrate 302, excluding the input 222 and output 224 and space between the input 222 and ground and between the output 224 and ground 40. In still other embodiments, the ground 40 may not be a single terminal on the device substrate 20 but may be two or more terminals, e.g., a generally rectangular shaped ground 40 may extend on each side of the input 222 and the output 224 from one end to the opposite end of the filter 200 such that the device 10 includes two ground terminals in contact with the vias 228. In yet other embodiments, the ground 40 may not be disposed at the filter 200 but one or more vias may be electrically connected to the ground 40 defined elsewhere on the device 10 using any suitable electrical connection between the via(s) 228 and ground 40.

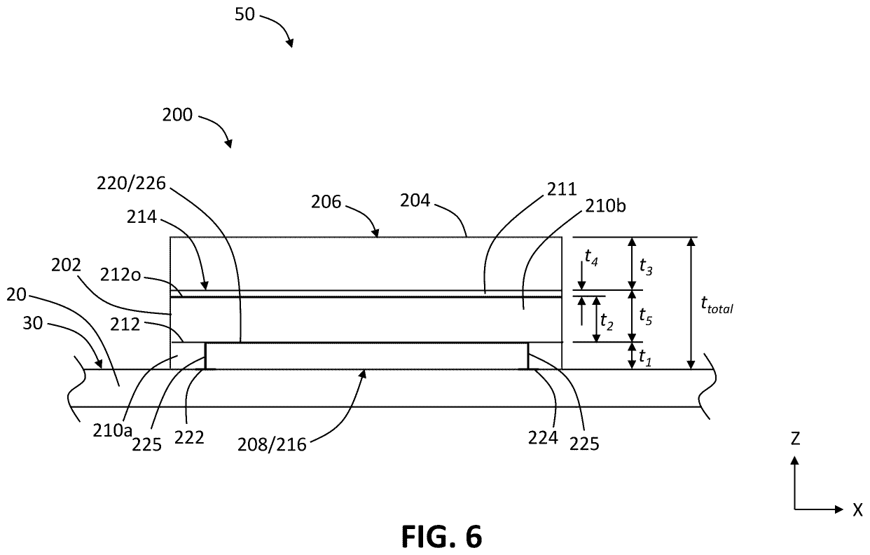

Turning to FIG. 6, a schematic cross-section view is provided of the assembly 50 including the filter 200. As shown in FIG. 6, the signal path 220, formed from one or more elements 226 as described above, is disposed on a conductive layer 212. The conductive layer 212 is sandwiched in a plurality of dielectric layers 210 (which, for the sake of clarity, are not shown individually in FIG. 6), e.g., the conductive layer 212 is positioned between a first plurality 210a of dielectric layers 210 and a second plurality 210b of dielectric layers 210 such that the conductive layer 212 is positioned at a location along the Z-direction between the top 214 and the bottom 216 of the substrate 202. The bottom 216 of the substrate 202 is positioned adjacent the mounting surface 30 of the device 10. In the depicted embodiment, the first plurality 210a of dielectric layers 210 has a thickness t₁ in the Z-direction, and the second plurality 210b of dielectric layers 210 has a thickness t₂ in the Z-direction. Accordingly, the conductive layer 212 is positioned at the location t₁ along the Z-direction from the bottom 216 of the substrate 202.

The thickness t₁ of the first plurality 210a of dielectric layers 210 may be about 200 μm or less. For example, the thickness t₁ of the first plurality 210a of dielectric layers 210 may be within a range of about 20 μm to about 200 μm, such as within a range of about 25 μm to about 150 μm, a range of about 50 μm to about 120 μm, or a range of about 60 μm to about 90 μm. As such, in embodiments in which the conductive layer 212 includes a plurality of elements 226 formed as resonators, the resonators are disposed at a location within the substrate 202 of about 200 μm or less from an outer surface (such as the bottom surface 216) of the substrate 202.

The thickness t₂ of the second plurality 210b of dielectric layers 210 may be about 1000 μm or less. For instance, the thickness t₂ of the second plurality 210b of dielectric layers 210 may be within a range of about 100 μm to about 1000 μm, such as within a range of about 200 μm to about 800 μm, a range of about 300 μm to about 700 μm, or a range of about 400 μm to about 600 μm.

As also shown in FIG. 6, the outer conductive layer 212-o is positioned on the second plurality 210b of dielectric layers 210. As such, the outer conductive layer 212-o is positioned at a location along the Z-direction from the bottom 216 of the substrate 202 that is equal to the sum of the thickness t₁ of the first plurality 210a of dielectric layers 210 and the thickness t₂ of the second plurality 210b of dielectric layers 210. Further, in some embodiments, the substrate 202 may include an outer layer 211, which may be, e.g., a solder mask or layer of dielectric material (such as a third plurality of dielectric layers 210). The outer layer 211 may have a thickness t₄ in the Z-direction, which may be about 200 μm or less. For example, the thickness t₄ of the outer layer 211 may be within a range of about 10 μm to about 200 μm, such as within a range of about 20 μm to about 150 μm, a range of about 30 μm to about 120 μm, or a range of about 50 μm to about 90 μm.

Accordingly, the conductive layer 212 may be positioned at a thickness or location within the substrate 202 along the Z-direction that is a thickness t₅ from the top 214 of the substrate 202. The thickness t₅ may be equal to the sum of the thickness t₂ of the second plurality 210b of dielectric layers 210 and the thickness t₄ of the outer layer 211, and as such, the thickness t₅ may be about 1200 μm or less.

As further illustrated in FIG. 6, the cover 204 may have a thickness t₃ in the Z-direction. The cover thickness t₃ may be about 1000 μm or less. For example, the cover thickness t₃ may be within a range of about 100 μm to about 1000 μm, such as within a range of about 200 μm to about 800 μm, a range of about 300 μm to about 700 μm, or a range of about 400 μm to about 600 μm.

It will be appreciated that the thickness of the substrate 202 is the sum of the thickness t₁ of the first plurality 210a of dielectric layers 210 and the thickness t₅, as shown in FIG. 6. As such, the thickness of the substrate 202 may be about 1400 μm or less, such as about 1000 μm or less, about 800 μm or less, about 500 μm or less, or about 400 μm or less. Moreover, the total thickness tₜₒₜₐₗ of the filter 200 is the sum of the thickness of the substrate 202 and the cover 204, or the sum of the thickness t₁ of the first plurality 210a of dielectric layers 210, the thickness t₅, and the cover thickness t₃ of the cover 204. As such, the thickness of the substrate 202 may be about 2400 μm or less, such as about 2000 μm or less, about 1500 μm or less, about 1000 μm or less, about 800 μm or less, about 500 μm or less, or about 400 μm or less. For instance, the total thickness tₜₒₜₐₗ of the filter 200 may be within a range of about 230 μm to about 2400 μm, a range of about 300 μm to about 1500 μm, a range of about 400 μm to about 1000 μm, or a range of about 400 μm to about 800 μm.

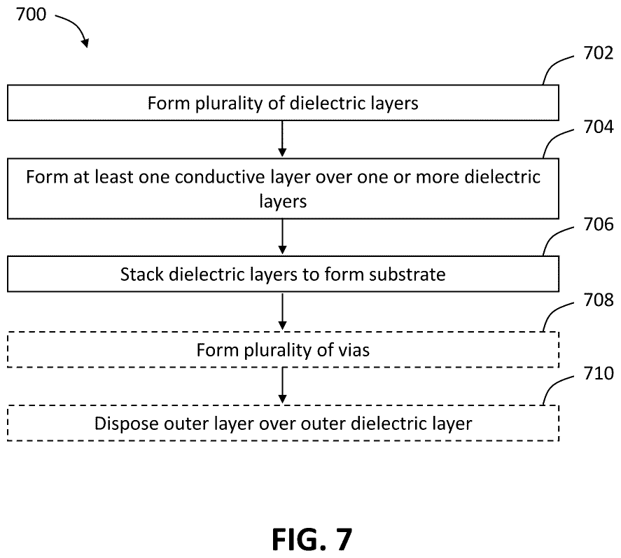

Referring to FIG. 7, the present subject matter also includes methods 700 for forming filters 100, 200 and methods for forming assemblies as described herein. In various embodiments, the steps of the method 700 may be performed in any suitable order using any appropriate technique.

As shown at (702) in FIG. 7, a method 700 for forming a filter 100, 200 may include forming a plurality of dielectric layers, such as the dielectric layers 110 of the filter 100 or the dielectric layers 210 of the filter 200. The method 700 also includes at (704) forming a at least one conductive layer, e.g., the conductive layer 112 of the filter 100 or the conductive layer 212 of the filter 200. As shown at (706), the method 700 includes stacking the plurality of dielectric layers 110, 210 in a Z-direction to form a substrate 102, 202 having a top 114, 214 and a bottom 116, 216. For example, in some embodiments, a conductive layer 112 is formed over a dielectric layer 110 of the plurality of dielectric layers 110. When the plurality of dielectric layers 110 are stacked in the Z-direction, the conductive layer 112 is stacked with the plurality of dielectric layers 110 such that the conductive layer 112 is spaced apart along the Z-direction from both a top 114 and a bottom 116 of the substrate 102. As another example, in other embodiments, a conductive layer 212 is formed over a dielectric layer 210 of the plurality of dielectric layers 210, and an outer conductive layer 212-o is formed over an outer dielectric layer 210-o of the plurality of dielectric layers 210. When the plurality of dielectric layers 210 are stacked in the Z-direction, the conductive layer 212 is stacked with the plurality of dielectric layers 210 such that the conductive layer 212 is spaced apart along the Z-direction from both a top 214 and a bottom 216 of the substrate 202, and the outer conductive layer 212-o is positioned at the top of the stack of the plurality of dielectric layers 210.

As shown at (708), the method 700 optionally may include defining a plurality of vias 228 along a perimeter P of the substrate 202. For instance, the plurality of vias 228 may be defined in the filter 200 such that the plurality of vias 228 extend from the outer conductive layer 212-o of the plurality of conductive layers 212 to the bottom 216 of the filter substrate 202. Further, as shown at (710), the method 700 optionally may include disposing an outer layer 211 over the outer dielectric layer 210-o (over which may be formed the outer conductive layer 212-o as described with respect to FIGS. 4 through 6).

In methods of forming an assembly 50 including a filter 100, 200 as described herein, the method may include attaching the filter 100, 200 to a mounting surface 30 defined by a device substrate 20 of a device 10. The filter 100, 200 may be mounted on the device 10 such that the dielectric layers 110, 210 and the conductive layers 112, 212 of the filter 100, 200 extend parallel to the mounting surface 30. Moreover, in some embodiments, one or more vias 228 of the filter 200 may be electrically connected to a ground 40 of the device 10.

### Examples

The various embodiments of the filter described herein may find application in any suitable type of electrical component. The filter may find particular application in devices that receive, transmit, or otherwise employ high frequency radio signals. Example applications include smartphones, signal repeaters (e.g., small cells), relay stations, and radar.

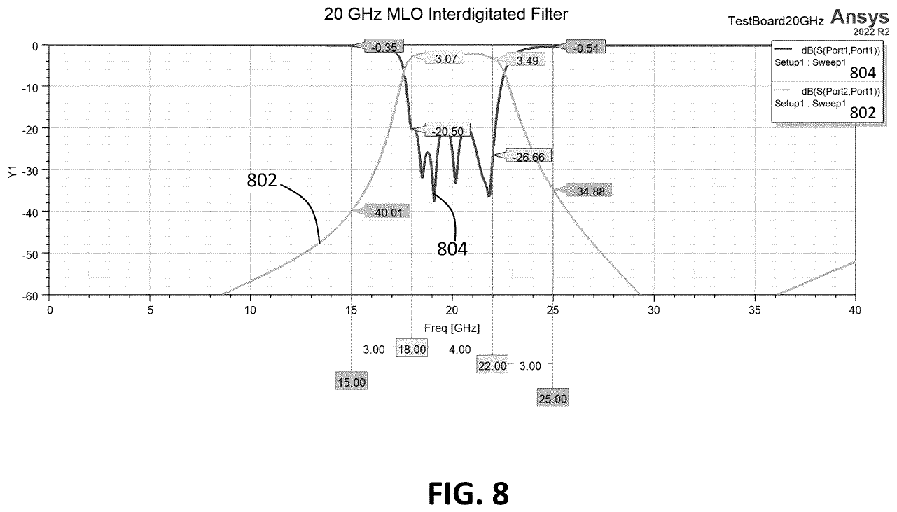

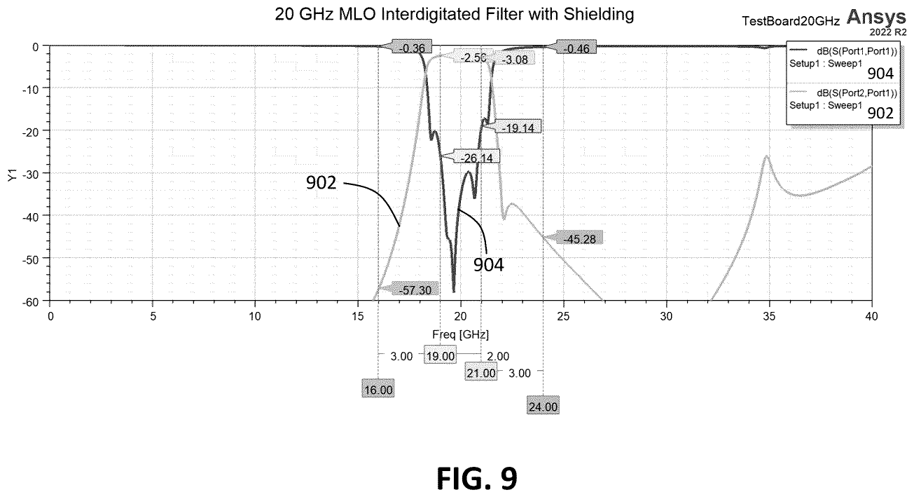

Computer modeling was used to simulate multilayer filters according to aspects of the present disclosure. FIGS. 8 and 9 present simulation data for the various filters. More particularly, FIG. 8 presents simulated insertion loss (S21) values 802 and simulated return loss (S11) values 804 from 0 GHz to 40 GHz, with a passband frequency range from about 18 GHz to about 22 GHz, for a filter configured as described above with respect to the filter 100. FIG. 9 presents simulated insertion loss (S21) values 802 and simulated return loss (S11) values 804 from 0 GHz to 40 GHz, with a passband frequency range from about 19 GHz to about 21 GHZ, for a filter configured as described above with respect to the filter 200 having a grounded shield 230. It should be understood that the dimensions described with respect to these exemplary filters are merely given as examples and do not limit the scope of the present disclosure.

Referring to FIG. 8, insertion loss 802 and return loss 804 are illustrated as modeled for an exemplary filter 100 having a conductive layer 112 disposed 120 μm from the bottom surface of the filter 100, i.e., 120 μm of dielectric material was disposed between the conductive material of the conductive layer 112 and the bottom surface of the filter. The modeled filter 100 had a length in the X-direction of 4.5 mm and a width in the Y-direction of 3.2 mm, and the element line widths w were 291.5 μm. Metallization along the bottom of the modeled filter 100 had a thickness of 18 μm, and the elements 126 of the conductive layer 112 had a thickness of 18 μm. The total thickness of the modeled filter 100 was 894 μm.

As shown in FIG. 8, at frequencies within the passband frequency range of about 18 GHz to about 22 GHZ, the insertion loss 802 was greater than about −3.5 dB and, generally, was greater than about −2 dB. Further, the return loss 804 within the passband frequency range was generally less than about −20 dB. As shown in FIG. 8, the return loss 804 ranged from a high of about −20.5 dB to a low of about −38 dB.

Referring to FIG. 9, insertion loss 902 and return loss 904 are illustrated as modeled for an exemplary filter 200 having a conductive layer 212 disposed 120 μm from the bottom surface of the filter 200 and having a plurality of vias 228 and a shield 230. The modeled filter 200 had a length in the X-direction of 4.5 mm and a width in the Y-direction of 3.2 mm, and the element line widths w were 291.5 μm. Metallization along the bottom of the modeled filter 200 had a thickness of 18 μm, and the elements 226 of the conductive layer 212 had a thickness of 18 μm. The total thickness of the modeled filter 200 was 894 μm.

As shown in FIG. 9, at frequencies within the passband frequency range of about 19 GHz to about 21 GHZ, the insertion loss 902 was greater than about −3 dB and, generally, was greater than about −2.5 dB. Further, the return loss 904 within the passband frequency range was generally less than about −19 dB. As shown in FIG. 9, the return loss 904 ranged from a high of about −19.14 dB to a low of about −58 dB.

These and other modifications and variations of the present invention may be practiced by those of ordinary skill in the art, without departing from the spirit and scope of the present invention. In addition, it should be understood that aspects of the various embodiments may be interchanged both in whole or in part. Further, those of ordinary skill in the art will appreciate that the foregoing description is by way of example only and is not intended to limit the invention so further described in such appended claims.

What is claimed is:

1. A filter, comprising:
a plurality of dielectric layers, the plurality of dielectric layers stacked in a Z-direction to form a substrate having a top and a bottom; and
at least one conductive layer formed over a dielectric layer of the plurality of dielectric layers,
wherein the at least one conductive layer is positioned at a location along the Z-direction between the top and the bottom of the substrate, and
wherein the location along the Z-direction is about 200 μm or less from the bottom of the substrate.

2. The filter of claim 1, wherein the at least one conductive layer defines a signal path, and wherein the signal path comprises an input and an output.

3. The filter of claim 2, wherein the signal path comprises a plurality of elements formed from a conductive material, wherein the plurality of elements includes at least one element having an element line width in an X-Y plane extending perpendicular to the Z-direction, and wherein the element line width decreases as the location along the Z-direction of the at least one conductive layer decreases such that the conductive layer is closer to the bottom of the substrate.

4. The filter of claim 3, wherein the plurality of elements is a plurality of resonators.

5. The filter of claim 2, wherein an input contact pad is defined on the bottom of the substrate and an output contact pad is defined on the bottom of the substrate, and wherein at least one input via electrically connects the input of the signal path with the input contact pad and at least one output via electrically connects the output of the signal path with the output contact pad.

6. The filter of claim 1, wherein the substrate has a substrate thickness from the bottom to the top of the substrate along the Z-direction, and wherein the substrate thickness is about 500 μm or less.

7. The filter of claim 1, further comprising a cover formed over the substrate.

8. The filter of claim 7, wherein the cover has a cover thickness over the top of the substrate along the Z-direction, wherein the substrate has a substrate thickness from the bottom to the top of the substrate along the Z-direction, wherein a total thickness of the filter includes the substrate thickness and the cover thickness, and wherein the total thickness is about 600 μm or less.

9. The filter of claim 1, wherein the plurality of dielectric layers includes a first plurality of dielectric layers and a second plurality of dielectric layers, and wherein the at least one conductive layer is disposed between the first plurality of dielectric layers and the second plurality of dielectric layers such that the at least one conductive layer is sandwiched by the plurality of dielectric layers.

10. The filter of claim 1, wherein the plurality of dielectric layers is formed from a dielectric material having a dielectric constant less than about 20.

11. An assembly, comprising:
a device having a device substrate defining a mounting surface; and
a filter attached to the device substrate, the filter comprising:
a plurality of dielectric layers, the plurality of dielectric layers stacked in a Z-direction to form a substrate having a top and a bottom; and
at least one conductive layer formed over a dielectric layer of the plurality of dielectric layers,
wherein the at least one conductive layer is positioned at a location along the Z-direction between the top and the bottom of the substrate, and
wherein the location along the Z-direction is about 200 μm or less from the bottom of the substrate.

12. The assembly of claim 11, wherein the filter is attached to the mounting surface of the device substrate such that the bottom of the substrate of the filter is adjacent the mounting surface of the device substrate.

13. The assembly of claim 11, wherein the filter is attached to the mounting surface of the device substrate such that the plurality of dielectric layers and the at least one conductive layer extend parallel to the mounting surface.

14. The assembly of claim 11, wherein the at least one conductive layer defines a signal path, wherein the signal path comprises a plurality of resonators formed from a conductive material, and wherein the plurality of resonators includes at least one resonator having an element line width in an X-Y plane extending perpendicular to the Z-direction.

15. The assembly of claim 14, wherein the element line width decreases as the location along the Z-direction of the at least one conductive layer decreases such that the conductive layer is closer to the bottom of the substrate.

16. The assembly of claim 14, wherein an input contact pad is defined on the bottom of the substrate and an output contact pad is defined on the bottom of the substrate, and wherein at least one input via electrically connects an input of the signal path with the input contact pad and at least one output via electrically connects an output of the signal path with the output contact pad.

17. The assembly of claim 11, wherein the substrate of the filter has a substrate thickness from the bottom to the top of the substrate along the Z-direction, and wherein the substrate thickness is about 500 μm or less.

18. The assembly of claim 11, further comprising a cover formed over the substrate of the filter, wherein the cover has a cover thickness over the top of the substrate along the Z-direction, wherein the substrate has a substrate thickness from the bottom to the top of the substrate along the Z-direction, wherein a total thickness of the filter includes the substrate thickness and the cover thickness, and wherein the total thickness is about 600 μm or less.

19. The assembly of claim 11, wherein the plurality of dielectric layers of the filter includes a first plurality of dielectric layers and a second plurality of dielectric layers, and wherein the at least one conductive layer of the filter is disposed between the first plurality of dielectric layers and the second plurality of dielectric layers such that the at least one conductive layer is sandwiched by the plurality of dielectric layers.

20. A method for forming a filter, the method comprising:
forming a plurality of dielectric layers;
forming at least one conductive layer over a dielectric layer of the plurality of dielectric layers; and
stacking the plurality of dielectric layers in a Z-direction to form a substrate having a top and a bottom,
wherein the at least one conductive layer is positioned at a location along the Z-direction between the top and the bottom of the substrate, and
wherein the location along the Z-direction is about 200 μm or less from the bottom of the substrate.
